(19) United States
(12) Patent Application Publication
(10) Pub. No.: US 2019/0198748 A1
(43) Pub. Date: Jun. 27, 2019

(54) SELF-SENSING BENDING ACTUATOR

(71) Applicant: Santosh Kumar BEHERA, San Jose, CA (US)

(72) Inventor: Santosh Kumar BEHERA, San Jose, CA (US)

(21) Appl. No.: 15/854,698

(22) Filed: Dec. 26, 2017

(51) Int. Cl. H01L 41/09; H01L 41/04; H01L 41/047; H01L 41/18; H01L 41/113

(52) U.S. Cl. CPC H01L 41/094; H01L 41/042; H01L 41/1136; H01L 41/18; H01L 41/1132; H01L 41/0477

(57) ABSTRACT

Disclosed is a self-sensing bending actuator. The self-sensing bending actuator includes a stack of layers including a first piezoelectric bending element and a second piezoelectric bending element, a metallic layer disposed between the first piezoelectric bending element and the second piezoelectric bending element such that the metallic layer is electrically coupled to the first piezoelectric bending element and the second piezoelectric bending element, an insulating layer disposed on the second piezoelectric bending element, and a sensing element disposed on the insulating layer. In the disclosed self-sensing bending actuator, the one or more of the first piezoelectric bending element and the second piezoelectric bending element are constructed of PZT-5H material, the metallic layer is composed of brass material, the insulating layer is composed of a polyimide material such as Kapton, and the sensing element is constructed of one of more of polyvinylidene fluoride and polyvinylidene difluoride (PVDF) material.

### TECHNICAL FIELD

The present disclosure relates generally to actuators and, more particularly to, a self-sensing bending actuator.

### BACKGROUND

In the past few decades, there has been a tremendous interest in the use of piezoelectric sensors and actuators for control and sensing applications. Piezoelectric bending actuators amplify the small strains in the piezoelectric material to usable displacement at the tip which can be of the order of millimeters. The large tip displacement of the bending actuators could be leveraged to develop complex actuating mechanisms. Piezoelectric elements have been used successfully in the closed loop control of a variety of active structures including beams, plates, shafts, trusses, etc. Some of the attributes, which have made piezoelectric actuators particularly attractive for active control, include the large useful bandwidth, the efficient conversion of electrical to mechanical energy, the ability to perform shape control, and the mechanical simplicity of the piezoelectric actuator.

Conventionally, actuators need external sensors to estimate displacement or stiffness of external load, which adds to the cost, and in some cases may have poor results or are difficult to implement due to space constraints. For instance, available force based sensors are afflicted with low resolution and low bandwidth; strain gauge based sensors have low frequency bandwidth and need alteration of host structure, and laser based sensors are expensive, bulky and need additional space as well as mounting system to incorporate. With the advancement in piezoelectric actuators, there has been a growing interest in development of piezoelectric element in which the actuator and sensor are combined into a single unit, sometimes known as a self-sensing actuator. A self-sensing actuator is a special kind of actuator that has the inherent capability to measure its own state (displacement, force, speed etc.) without the need for an external sensor. The in-built sensing is due to the inherent property of the material used in making the actuator or an independent sensing mechanism that is integrated with the main body of the actuator.

Another benefit of a self-sensing actuator is that the sensor and actuator are truly collocated. Collocated control has been shown to have a number of advantages relating to the closed loop stability of the structure. For instance, in the absence of actuator and sensor dynamics, structures controlled with collocated velocity feedback are unconditionally stable at all frequencies. However, existing self-sensing piezoelectric actuators mostly utilize the same piezoelectric layer(s) for actuation as well as sensing which requires complex electronic circuitry to decode the sensing and actuation signals or have one dedicated sensor layer along with only one dedicated actuator layer that, usually, results in low displacement output.

In light of the foregoing discussion, there exists a need to overcome the aforementioned drawbacks of conventional self-sensing piezoelectric actuator.

### SUMMARY

Various embodiments of the present disclosure provide a self-sensing bending actuator.

In one aspect of the present disclosure, a self-sensing bending actuator is disclosed. The self-sensing bending actuator includes at least two layers of bending elements. The self-sensing bending actuator also includes a metallic layer disposed between each of the layers of bending elements. The self-sensing bending actuator further includes an insulating layer disposed on at least one of the layers of bending elements. The self-sensing bending actuator further includes a sensing element disposed on the insulating layer.

In another aspect of the present disclosure, a self-sensing bending actuator is disclosed. The self-sensing bending actuator includes one or more layers of piezoelectric bending elements constructed of PZT-5H material. The piezoelectric bending elements are configured to generate a strain therein resulting in displacement of the beam. The self-sensing bending actuator also includes an insulating layer disposed on at least one of the layers of piezoelectric bending elements. The insulating layer is composed of a polyimide material. The self-sensing bending actuator further includes a sensing element disposed on the insulating layer. The sensing element is constructed of one of more of polyvinylidene fluoride and polyvinylidene difluoride (PVDF) material. The sensing element is configured to estimate the tip displacement therein.

In yet another aspect of the present disclosure, a self-sensing bending actuator is disclosed. The self-sensing bending actuator includes a support body. The self-sensing bending actuator further includes a stack of layers cantilevered on the support body. The stack of layers includes a first piezoelectric bending element and a second piezoelectric bending element. The stack of layers further includes a metallic layer disposed between the first piezoelectric bending element and the second piezoelectric bending element. The metallic layer is electrically coupled to the first piezoelectric bending element and the second piezoelectric bending element. The stack of layers further includes an insulating layer disposed on the second piezoelectric bending element. The stack of layers further includes a sensing element disposed on the insulating layer.

Other aspects and example embodiments are provided in the drawings and the detailed description that follows.

### BRIEF DESCRIPTION OF THE FIGURES

For a more complete understanding of example embodiments of the present technology, reference is now made to the following descriptions taken in connection with the accompanying drawings in which:

FIG. 1 is a diagrammatic view of a self-sensing bending actuator, in accordance with an example embodiment;

FIG. 2 is a cross-sectional view showing the arrangement of various layers in the self-sensing bending actuator, in accordance with an example embodiment;

FIG. 3 is a cross-sectional view showing the arrangement of various layers in the self-sensing bending actuator, in accordance with another example embodiment; and

FIG. 4 is a plot showing a relationship between a tip displacement against an actuator thickness ratio for the self-sensing bending actuator, in accordance with an example embodiment.

The drawings referred to in this description are not to be understood as being drawn to scale except if specifically noted, and such drawings are only exemplary in nature.

### DETAILED DESCRIPTION

In the following description, for purposes of explanation, numerous specific details are set forth in order to provide a thorough understanding of the present disclosure. It will be apparent, however, to one skilled in the art that the present disclosure can be practiced without these specific details.

Reference in this specification to “one embodiment” or “an embodiment” means that a particular feature, structure, or characteristic described in connection with the embodiment is included in at least one embodiment of the present disclosure. The appearance of the phrase “in an embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described, which may be requirements for some embodiments but not for other embodiments.

Moreover, although the following description contains many specifics for the purposes of illustration, anyone skilled in the art will appreciate that many variations and/or alterations to said details are within the scope of the present disclosure. Similarly, although many of the features of the present disclosure are described in terms of each other, or in conjunction with each other, one skilled in the art will appreciate that many of these features can be provided independently of other features. Accordingly, this description of the present disclosure is set forth without any loss of generality to, and without imposing limitations upon, the present disclosure.

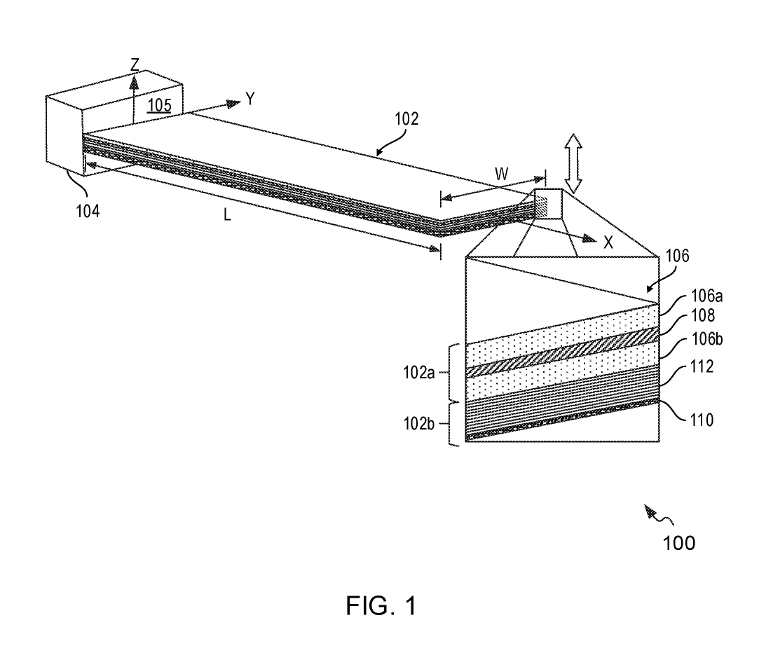

Referring now to the drawings, FIG. 1 illustrates a diagrammatic view of a self-sensing bending actuator (generally referenced by the numeral 100). In accordance with an embodiment of the present disclosure, the self-sensing bending actuator 100 is a piezoelectric bending actuator. Hereinafter, the terms “self-sensing bending actuator,” “bending actuator,” “piezoelectric bending actuator,” and “piezoelectric actuator” have been used interchangeably without any limitations. As may be understood, an actuator is a device that converts some form of energy to mechanical motion. A piezoelectric actuator, in particular, converts electrical energy into mechanical motion using principle of the inverse piezoelectric effect. The term “piezoelectric effect” refers to the conversion of mechanical energy to electrical energy, and this effect is used in the construction of piezoelectric sensors and energy harvesters; whereas the term “inverse piezoelectric effect” refers to the conversion of electrical energy to mechanical energy, and this effect is used in the construction of piezoelectric actuators. The inverse piezoelectric effect causes a change in length in these types of materials when an electrical voltage is applied. The self-sensing bending actuator 100 is designed to amplify the small strain of piezoelectric materials that results from the inverse piezoelectric effect in order to achieve a usable displacement. The generated mechanical motion may be used to drive a mechanism and to accomplish a task like opening or closing a camera shutter, moving a piston rod to control the flow of materials in an assembly line or to move a relay mechanism in a switching electric circuit, to name a few examples.

The self-sensing bending actuator 100 includes a stack of layers (collectively referred to by the numeral 102) and having an actuator potion 102a and a sensing potion 102b defined therein, as will be discussed in detail in the subsequent paragraphs. As illustrated in FIG. 1, the self-sensing bending actuator 100 may include a support body 104 which supports the various elements therein. In the illustrated example, the stack of layers 102 is cantilevered on the support body 104, i.e. the stack of layers 102 is supported in the form of a cantilever beam. The support body 104 may be constructed of any suitable insulating material, such as, but not limited to, plastic, fiberglass, asbestos, Teflon®, rubber, or any other electrically insulating polymer including polyurethane, polystyrene, etc. The support body 104 could also be made of stainless steel or any other metal. The support body 104 may be a rigid structure in order to hold the various functional material layers 102 of the self-sensing bending actuator 100. Although, the support body 104 is shown to have a generally cuboidal shape, it may be understood that the support body 104 may have any other suitable shape based on the application of the self-sensing bending actuator 100. In the present example, where the self-sensing bending actuator 100 is shown in the form of a cantilever beam, the support body 104 may include a groove or the like (not shown) formed in one of the end surfaces, such as surface 105 to support the stack of layers 102 of the self-sensing bending actuator 100.

In the self-sensing bending actuator 100 of the present disclosure, the stack of layers 102 includes one or more bending elements 106 (also sometimes referred to as actuator layers 106), a metallic layer 108 disposed between the bending elements 106 for providing support and electrical contact, a sensing element 110, and an insulating layer 112 separating the sensing element 110 from the immediate bending element 106. In the present example, the bending elements 106 and the metallic layer 108 therebetween define the actuator portion 102a of the self-sensing bending actuator 100, and the sensing element 110 herein along with the insulating layer 112 define the sensing portion 102b of the self-sensing bending actuator 100. This combination of the actuator portion 102a and the sensing portion 102b within the single unit makes the present device a self-sensing bending actuator.

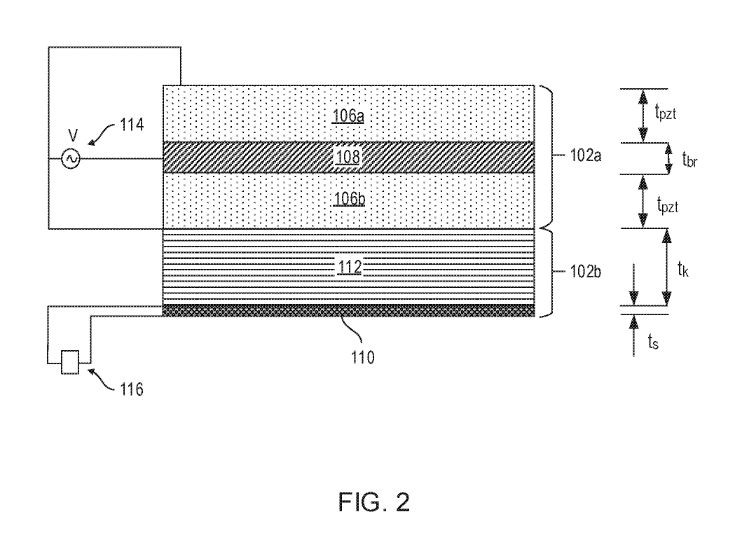

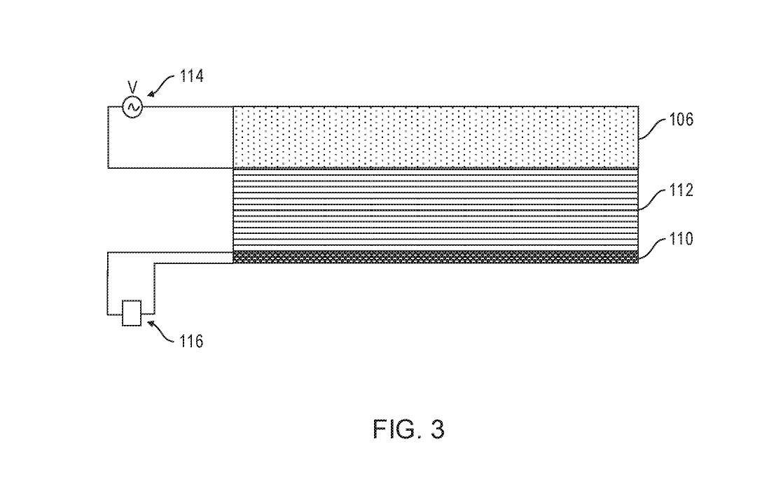

In an embodiment of the present disclosure, the self-sensing bending actuator 100 is a 5-layered self-sensing actuator. In such arrangement, the self-sensing bending actuator 100 includes two layers of the bending elements 106 (bimorph structure), as shown in more detail in FIG. 2. In alternate embodiments, the self-sensing bending actuator 100 may include one layer of the bending element 106 (unimorph structure) as shown in FIG. 3. Further, the self-sensing bending actuator 100 may have more than two layers of the bending elements 106, i.e. the self-sensing bending actuator 100 may be a multi-layered cantilever beam, without departing from the scope of the present disclosure. In FIG. 2, the actuator portion 102a of the self-sensing bending actuator 100 has been shown to include two layers of the bending elements 106, a first bending element 106a (positioned at top as shown in FIG. 2) and a second bending element 106b (positioned lower as shown in FIG. 2). Each of the one or more bending elements 106 is a smart material beam that bends in response to an applied electrical signal. In the present embodiment, the bending elements 106 are piezoelectric layers, and the two terms have been interchangeably used in the present disclosure. Although the self-sensing bending actuator 100 has been described in terms of using piezoelectric layers as bending elements 106, it may be contemplated by a person skilled in the art that the self-sensing bending actuator 100 may be realized with any other smart material, such as, but not limited to, magnetostrictive or shape memory materials.

In an embodiment, the bending elements 106 are constructed of PZT-5H layers (where PZT stands for lead zirconate titanate). PZT-5H is chosen as the actuator material due to its high piezoelectric coefficient, so that the piezoelectric layers 106 provides a high bending or tip displacement as well as blocked force, where blocked force is defined as the maximum force output of a bending piezoelectric actuator at a given voltage when the displacement is completely blocked. Further, ease of availability as well as low price of PZT-5H compared to other commercial piezoelectric materials makes it a suitable choice. Alternatively, the bending elements 106 may be composed of any appropriate material such as lead magnesium niobate-lead titanate solid solutions, strontium lead titanate, quartz silica, piezoelectric ceramic lead zirconate and titanate (PZT), piezoceramic-polymer fiber composites, and the like. Further, the metallic layer 108 is composed of brass material. Brass is chosen primarily because of its relatively good electrical conductivity for providing electrical contact between the two piezoelectric layers 106a, 106b, and low stiffness for allowing maximum displacement of the self-sensing bending actuator 100, and further for its ability to be formed into thin sheets. Further, the sensing element 110 is constructed of polyvinylidene fluoride, or polyvinylidene difluoride, (PVDF) layer. PVDF is chosen for the sensing element 110 due to its high sensing resolution, ability to be formed into micrometer-sized thin sheets and low stiffness so that it offers as little resistance as possible to the motion induced by the piezoelectric layers 106. Further, the insulating layer is composed of Kapton® layer which is placed between the PZT-5H layer 106b and the PVDF layer 110. Kapton is a polyimide film with the chemical name poly (4,4′-oxydiphenylene-pyromellitimide), and with its good dielectric qualities, large range of temperature stability and its availability as thin sheets have made it a preferred material for use as insulating material in the present configuration. Further, layers of adhesive compositions may be employed to adhere the various layers with each other. It may be understood that the mentioned materials for various layers 102 are preferred materials for the self-sensing bending actuator 100; however, these materials may be replaced with other suitable materials of substantially similar properties and thus shall not be construed as limiting to the present disclosure.

In the self-sensing bending actuator 100, the two piezoelectric layers 106a, 106b act as the actuator layers and are responsible for generating a displacement as well as force output on the application of an electrical voltage. For this purpose, the piezoelectric layers 106a, 106b are connected via an electric circuit 114, as shown schematically in FIG. 2. Specifically, in the electric circuit 114, the two outer surfaces of the piezoelectric layers 106a, 106b are connected together electrically via a conductive wire or the like. Also, the inner surfaces of the piezoelectric layers 106a, 106b are already disposed in electrical contact via the conductive brass layer 108. As illustrated, in the electric circuit 114, a pair of wire leads are attached to the brass layer 108 and to at least one of the outer surfaces of the piezoelectric layers 106a, 106b in order to provide the potential difference between the two surfaces of the corresponding piezoelectric layers 106a, 106b. To actuate the bending actuator, a voltage is applied to these wire leads which results in the same voltage being applied across each of the two piezoelectric layers 106a, 106b. It may be contemplated that the electrical signal is generated by a computer or a function generator and is fed to the piezoelectric layers 106a, 106b after amplification. The design and configuration of such circuitry is well known in the art, and thus have not been described herein for the brevity of the present disclosure.

In the self-sensing bending actuator 100, the two piezoelectric layers 106a, 106b are polarized in the same direction. Each of the piezoelectric layers 106a, 106b has orthotropic symmetry with respect to its material properties such that the material properties are the same along X and Y directions and different along Z direction. The piezoelectric layers 106a, 106b are polarized in the thickness direction, i.e. along the Z direction. When a voltage is applied across the thickness direction of each layer, it either expands or contracts. In the electric circuit 114, the wiring is done such that the inner surfaces of the two piezoelectric layers 106a, 106b are at a same first potential while the outer surfaces are at a same second potential. This ensures that the field directions are opposite to each other in the two piezoelectric layers 106a, 106b. When a positive voltage is applied, the electric field is aligned with the direction of polarization with the first piezoelectric layer 106a, whereas the electric field and polarization are in opposite directions for the second piezoelectric layer 106b. This causes the first piezoelectric layer 106a to expand and the second piezoelectric layer 106b to contract resulting in the bending or up-down movement of the cantilever beam as formed by the stack of layers 102, along the Z direction (as shown by means of a double-sided arrow in FIG. 1).

Furthermore, the self-sensing bending actuator 100 of the present disclosure also has self-sensing characteristics. That is, the present self-sensing bending actuator 100 is capable of estimating its own deflection without using any external sensor. For this purpose, the PVDF layer 110 acts as the sensor to estimate the tip displacement of the self-sensing bending actuator 100, in response to the applied voltage. For example, when a voltage is applied as input across the actuator layers 106a, 106b, the applied voltage results in bending of the cantilever beam structure of the bending actuator 100. The strain developed in the PVDF layer 110 due to the bending generates a charge across the PVDF layer 110 because of the piezoelectric effect. A pair of leads are connected across the PVDF layer 110 to fed the charge generated in response to the tip displacement into a convertor circuit 116 (as shown in FIG. 2). Sometimes, the generated charge from the PVDF layer 110 is amplified using the charge amplifier. The convertor circuit 116 provides a voltage output based on the fed charge which is proportional to the tip displacement and may be read using any available means, such as an analog or a digital meter, a display, etc. known in the art. For a given applied voltage, the tip displacement is related to the charge generated across the PVDF layer as:

Uₜᵢₚ=kₛₛ*V_{PVDF}

Wherein, Uₜᵢₚ is the predicted tip displacement, kₛₛ is the sensor constant that relates the tip displacement and V_{PVDF} is the voltage generated across the PVDF layer 110. The sensor constant is experimentally determined by linear curve fit of the PVDF layer 110 voltage and the displacement measured using an external sensor.

It may be understood that the thickness of the various layers 102 affects the tip displacement achieved by the self-sensing bending actuator 100. Although increasing the thickness of the piezoelectric bending elements 106a, 106b should generally lead to more bending movement, but it may be noted that such increase in thickness may also increase the stiffness of the structure which adversely affects overall achieved tip displacement. Therefore, beyond a certain increase in thickness, there may be an actual drop in tip displacement; and thus the thickness of various layers may need to be optimized. It has been seen that the tip displacement generally increases as the total thickness is reduced demonstrating the inverse-square relationship between the tip displacement and thickness. Further, it may be understood that that the piezoelectric bending elements 106a, 106b have their maximum displacement at resonance. It is known that increasing the thickness of the piezoelectric bending elements 106a, 106b increases its natural frequency. Therefore, by tuning the frequency of the piezoelectric bending elements 106a, 106b to a desired value the achieved tip displacements may be varied depending on the type of application of the self-sensing bending actuator 100. Other parameters like length and width can be similarly modified to optimize certain geometrical parameters for the required frequency response, and thereby to achieve the desired performance objectives.

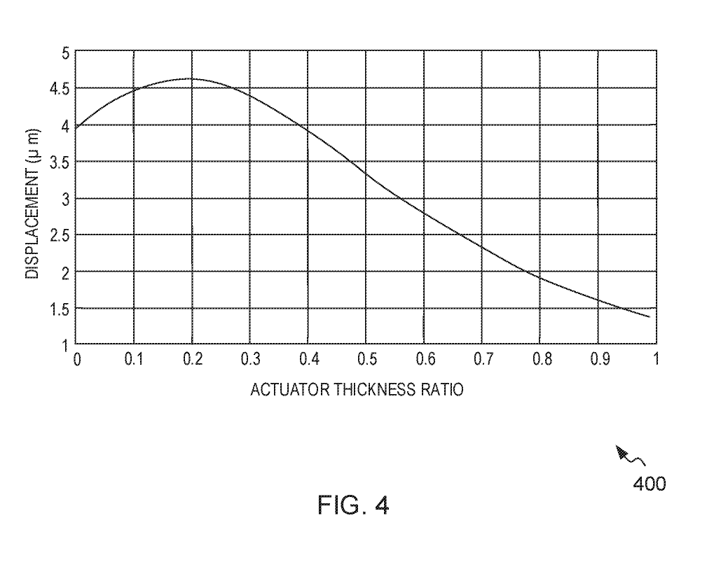

FIG. 4 shows a plot 400 of the tip displacement against the actuator thickness ratio for an exemplary input loading of ‘1 V’ for various actuator thickness ratios of the piezoelectric bending elements 106a, 106b, keeping the total thickness of the self-sensing bending actuator 100 constant. Herein, the actuator thickness ratio is defined as the ratio of the combined thickness of the two piezoelectric bending elements 106a, 106b and the total thickness of the self-sensing bending actuator 100. The plot 400 suggests the existence of an optimum thickness of the piezoelectric bending elements 106a, 106b that maximizes the tip displacement. The initial increase in tip displacement with increasing actuator thickness ratio may be due to the greater energy needed to overcome the resistance offered by the passive layers, i.e. the brass layer 108, the sensing element 110 and the insulating layer 112. As may be seen from FIG. 4, beyond a certain thickness fraction of about 0.20, increasing thickness of the actuator layers 106a, 106b also increases the overall stiffness and hence the tip displacement drops.

Based on the above, the present self-sensing bending actuator 100 may have any appropriate combination of dimensions. Further, the dimensions of various layers 102 may be non-uniform, e.g., the self-sensing bending actuator 100 may have a tapered configuration or the like without any limitations. In an exemplary embodiment, for a self-sensing bending actuator 100 with a length (L) of about 40 mm and a width of about 10 mm, the optimum thickness for various layers for achieving high tip displacement and high blocked force may be: PZT-5H thickness (t_{pzt}) of about 0.2 mm, Brass thickness (t_{br}) about 0.1 mm (making the overall thickness of the bimorph structure of the actuator portion 102a to be about 0.5 mm), Kapton thickness (tₖ) of about 0.28 mm, and PVDF thickness (tₛ) of about 28 μm. In one example, the PVDF layer 110 may be larger in length (L) than the other layers, for example, the PVDF layer 110 may be about 55 mm in length (L) while the other layers are about 40 mm in length (L). It may be understood that the given dimensions are exemplary only, and shall not be construed as limiting to the present disclosure in any manner.

The self-sensing bending actuator 100 of the present disclosure may be manufactured by stacking layers of various materials (as described above) in a suitable manner. First, the actuator portion 102a with the bimorph structure of the bending elements 106 is prepared by adhering the brass layer 108 to the first PZT-5H layer 106a and then the second PZT-5H layer 106b is pasted thereon, using a conductive epoxy. Further, a Kapton film 112 is attached to the formed bimorph structure by using a two-part epoxy adhesive and is left for about 24 hours to dry. To the free surface of Kapton film 112, one or more PVDF sheets 110 are attached using a high-shear adhesive, such as, for example, Loctite-380. Since, in one example, the PVDF sheets 110 are longer than the other layers, part of these may be free hanging. Herein, copper tapes with conductive adhesive are attached on each of these surfaces of the free hanging part. Further, in such case, a few layers of paper tape are attached to the inner surface of the copper tapes to prevent the two surfaces of the PVDF sheets 110 from shorting.

The self-sensing bending actuator 100 of the present disclosure has a number of desirable properties not easily achieved with a separate piezoelectric sensor and actuator. The self-sensing bending actuator 100 is more accurate due to the collocated arrangement of sensor and actuator elements. The modular design of the present bending actuator 100 allows for multiple bending actuators 100 to be stacked on top of each other in order to achieve higher tip displacement and/or force output. Thus, the self-sensing bending actuator 100 may be employed in many application areas, including micromanipulation, robotic end-effectors, deformable mirrors, high speed switches, tattoo machines, shakers and vibration based energy harvesting, to name a few. Furthermore, it may be contemplated by a person skilled in the art that the self-sensing bending actuator 100 of the present disclosure may conversely also be used to distinguish between objects of varying stiffness. Such feature may particularly be helpful in medical settings, in particular surgical applications and the like.

The materials selected from the present bending actuator 100 also provide several advantages. For example, PZT smart materials are chemically inert to most common chemicals, rigid, have higher Curie point, are capable of generating large tip displacements due to their high piezoelectric coupling coefficients, and are readily available at very competitive rates. Their dynamic range can extend up to a few kilohertz (kHz) which is sufficient for most needs. The electronic circuitry needed to drive and analyze the signals from piezoelectric materials requires a simple signal generator and a linear amplifier for the actuator mode and a charge amplifier for the sensor mode which are also inexpensive compared to the requirements for other smart materials. For instance, on the other hand, other possible materials for actuators, like EAP smart materials need a very high actuation voltage of the order of kV which again drives up the cost of the overall device. They are also costlier to manufacture compared to piezoelectric devices with no advantages over piezoelectric materials. Magnetostrictive materials work analogous to piezoelectric materials but the coupling is between magnetic and mechanical domains instead of electrical and mechanical domains as is the case for piezoelectric materials. Besides posing a high risk of injury due to the use of high magnetic fields, for example, during a surgical procedure where other magnetic devices may be in use, the technology has not been demonstrated experimentally and hence its applications is uncertain. Moreover, extremely high magnetic fields are needed to generate high force and displacement output which are impossible without sophisticated cooling technology and electromagnet coil design. This would drive up the production cost as well as maintenance cost of a device using magnetostrictive materials.

Due to utilization of two piezoelectric actuator layers 106a, 106b, the present bending actuator 100 generally provides a higher tip displacement as well as the blocked force output for the same applied voltage compared to an actuator utilizing a single PZT-5H layer as the actuator. This is because the extra actuator layer of PZT-5H provides an increase in displacement while the softer sensing layer adds sensing capabilities without significantly increasing the stiffness of the overall structure of the bending actuator 100. Furthermore, the geometry of the present bending actuator 100 is preferred over a conventional piezoelectric based actuator due to higher force and displacement output per unit input voltage as well as a higher PVDF sensor output per unit displacement. For example, in comparison to a self-sensing actuator design in which both the actuator and the sensor layers are PZT-5H such that a top PZT-5H layer is connected to the input voltage and acts as the actuator while a bottom piezoelectric layer generates a voltage in response to the displacement and acts as a passive sensor, the displacement and force output of such design would be lower than present bending actuator 100 for the same applied voltage. This is due to the fact that there is only one actuating layer in contrast with two actuating layers in the present bending actuator 100 and furthermore the PZT-5H layer would have a higher stiffness and hence such actuator would have a higher resistance to work against compared to the present bending actuator 100 with the sensing element 110 having relatively low elastic stiffness. Additionally, in comparison to a conventional 3-layered self-sensing actuator in which the actuator is made of PZT-5H and the sensor is made of PVDF such that a top PZT-5H layer is connected to the input voltage and acts as an actuator while the bottom PVDF piezoelectric layer generates a voltage in response to the displacement, the displacement and force output of such an actuator would be lower than the present self-sensing bending actuator 100 since there is only one actuating layer compared to two actuating layers in the present actuator 100.

Again, for example, comparing the present design of the bending actuator 100 against a conventional actuator with both the top as well as bottom layers acting as actuator as well as sensor layers, the present design would provide better overall results despite the conventional design expected to have a higher force and displacement output (since the Kapton and the PVDF layers are the additional layers against which the present design has to work against). In such conventional design, since both the actuation and sensor signals are read and/or generated through the same set of wires, they are prone to high noise. Using bridge circuits may provide a solution, but it needs an additional dummy sensor otherwise an accurate estimation of the capacitance of the piezoelectric layers is hard to achieve due to its variation with environmental factors. In contrast, the present design uses the same amplifier as the other designs and a charge amplifier to convert the PVDF sensor signals to usable voltage. Furthermore, using Kapton and PVDF materials for the insulating layer 112 and the sensing element 110, respectively, the overall stiffness of the present design is not substantially increased because PVDF is available in very thin sheets of up to 28 μm and has a low elastic stiffness while Kapton is an excellent insulator with very low elastic stiffness, thereby generally offsetting any disadvantage over the conventional design.

Embodiments of the present disclosure substantially eliminate or at least partially address the aforementioned problems in the background, and provide an improved self-sensing bending actuator. The unique geometry makes this design achieve a larger force and displacement output compared to conventional bending actuators with one actuating layer and one sensing layer. For example, the self-sensing bending actuator 100 is capable of generating a tip displacement of about 3.26 mm, and possibly more, at its resonant frequency and has a predicted blocked force output of about 1.6 N at its optimal thickness ratio of actuator layers. The choice of materials ensures that the device can be used in a medical setting without any risk of injury to patients in contrast to magnetic field based devices. The estimated tip displacement using its self-sensing capability (by measuring the PVDF sensor layer charge output) has higher signal-to-noise ratio than such ratio achieved by any external sensor, in addition to providing the benefit of collocated design.

The embodiments illustrated and described herein as well as embodiments not specifically described herein but within the scope of aspects of the invention constitute exemplary self-sensing bending actuator.

The benefits and advantages described above may relate to one embodiment or may relate to several embodiments. The embodiments are not limited to those that solve any or all of the stated problems or those that have any or all of the stated benefits and advantages.

The above description is given by way of example only and various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

What is claimed is:

1. A self-sensing bending actuator, comprising:
at least two layers of bending elements;
a metallic layer disposed between each of the at least two layers of bending elements;
an insulating layer disposed on at least one of the at least two layers of bending elements; and
a sensing element disposed on the insulating layer.

2. The self-sensing bending actuator as claimed in claim 1, wherein each of the at least two layers of bending elements is a piezoelectric bending element.

3. The self-sensing bending actuator as claimed in claim 2, wherein each of the at least two layers of bending elements is constructed of PZT-5H material.

4. The self-sensing bending actuator as claimed in claim 1, wherein the metallic layer is composed of brass material.

5. The self-sensing bending actuator as claimed in claim 1, wherein the insulating layer is composed of a polyimide material.

6. The self-sensing bending actuator as claimed in claim 5, wherein the polyimide material is Kapton.

7. The self-sensing bending actuator as claimed in claim 1, wherein the sensing element is constructed of one of more of polyvinylidene fluoride and polyvinylidene difluoride (PVDF) material.

8. The self-sensing bending actuator as claimed in claim 1 further comprising an electric circuit configured to apply a voltage across the at least two layers of bending elements in order to generate a tip displacement.

9. The self-sensing bending actuator as claimed in claim 8 further comprising a convertor circuit electrically connected across the sensing element and configured to measure a charge generated in the sensing element in response to the applied voltage, in order to estimate the tip displacement.

10. The self-sensing bending actuator as claimed in claim 1, wherein the metallic layer, the insulating layer and the sensing element have relatively lower elastic stiffness compared to the at least two layers of bending elements.

11. The self-sensing bending actuator as claimed in claim 1, wherein an actuator thickness ratio, defined as the ratio of the combined thickness of the layers of piezoelectric bending elements and the total thickness of the self-sensing bending actuator, is approximately 0.20.

12. A self-sensing bending actuator, comprising:
one or more layers of piezoelectric bending elements constructed of PZT-5H material, the piezoelectric bending elements configured to generate a tip displacement therein;
an insulating layer disposed on at least one of the one or more layers of piezoelectric bending elements, the insulating layer composed of a polyimide material; and
a sensing element disposed on the insulating layer and constructed of one or more of polyvinylidene fluoride and polyvinylidene difluoride (PVDF) material, the sensing element configured to estimate the tip displacement therein.

13. The self-sensing bending actuator as claimed in claim 12, wherein the polyimide material is Kapton.

14. The self-sensing bending actuator as claimed in claim 12, wherein the one or more layers of piezoelectric bending elements comprise at least two layers of piezoelectric bending elements.

15. The self-sensing bending actuator as claimed in claim 14 further comprising a metallic layer disposed between each of the at least two layers of piezoelectric bending elements, wherein the metallic layer is composed of brass material.

16. The self-sensing bending actuator as claimed in claim 15, wherein the metallic layer, the insulating layer and the sensing element have relatively lower elastic stiffness compared to the one or more layers of piezoelectric bending elements.

17. A self-sensing bending actuator, comprising:
a support body; and
a stack of layers cantilevered on the support body, the stack of layers comprising:
a first piezoelectric bending element;
a second piezoelectric bending element;
a metallic layer disposed between the first piezoelectric bending element and the second piezoelectric bending element, the metallic layer being electrically coupled to the first piezoelectric bending element and the second piezoelectric bending element;
an insulating layer disposed on the second piezoelectric bending element; and
a sensing element disposed on the insulating layer.

18. The self-sensing bending actuator as claimed in claim 17, wherein at least one of:
one or more of the first piezoelectric bending element and the second piezoelectric bending element are constructed of PZT-5H material;
the metallic layer is composed of brass material;
the insulating layer is composed of a polyimide material, the polyimide material comprising Kapton; and
the sensing element is constructed of one of more of polyvinylidene fluoride and polyvinylidene difluoride (PVDF) material.

19. The self-sensing bending actuator as claimed in claim 17, wherein the metallic layer, the insulating layer and the sensing element have relatively lower elastic stiffness compared to one or more of the first piezoelectric bending element and the second piezoelectric bending element.

20. The self-sensing bending actuator as claimed in claim 17, wherein an actuator thickness ratio, defined as the ratio of the combined thickness of the first piezoelectric bending element and the second piezoelectric bending element, and the total thickness of the self-sensing bending actuator, is approximately 0.20.
